(19) United States
(12) Patent Application Publication
(10) Pub. No.: US 2007/0187685 A1
(43) Pub. Date: Aug. 16, 2007

(54) THIN FILM TRANSISTOR AND THIN FILM TRANSISTOR ARRAY SUBSTRATE

(76) Inventor: Chih-Chung Tu, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,505

(22) Filed: Feb. 10, 2006

(51) Int. Cl. H01L 29/04

(52) U.S. Cl. 257/72

(57) ABSTRACT

A thin film transistor including a gate, a gate insulating layer, a channel layer, a spiral source and a spiral drain is provided. The gate insulating layer covers the gate. The channel layer is disposed on the gate insulating layer above the gate. The spiral source and the spiral drain are disposed on the channel layer above the gate. The spiral source and spiral drain are curled with each other. By the design of spiral source and spiral drain, the ratio of width/length (W/L) can be increased, and the C_{gd} is reduced as well.

### BACKGROUND OF THIS INVENTION

1. Field of this Invention

This invention relates to a thin film transistor (TFT), and more particularly to a TFT that may increase the ratio of the W/L of channel and reduce the gate-drain parasitic capacitance C_{gd}, so that the feed through voltage can be reduced efficiently.

2. Description of the Related Art

Because users can get information from display devices and then control the operation of apparatus, display devices have become important communication interfaces between humans and machines. Wherein, the liquid crystal displays (LCDs) are the emphases of development. In generally, a LCD comprises a TFTs array substrate, a color filter substrate and a liquid crystal layer disposed between the two substrates. Wherein, the TFT comprising gate, channel and source/drain are used for controlling the date written into the LCD.

FIG. 1 is a schematic top view of conventional TFTs array substrate. Referring FIG. 1, a plurality of pixel structures 110 arranged is disposed on a TFTs array substrate 100 to form an array. Wherein, each of pixel structures 110 comprises a scan line 112, a data line 114, a TFT 116 and a pixel electrode 118 corresponding to the TFT 116.

TFT 116 is used as a switch element of the pixel structure 110, and the scan line 112 and the data line 114 are used for providing an appropriate operation voltage to one of the pixel structures 110 selected thereby, then each of the pixel structures 110 is driven respectively to display images.

It should be noted that a portion of the scan line 112 is used as the gate 116a of the TFT 116, and a semiconductor layer 116b is formed directly on the scan line 112. Then, a source 116c and a drain 116d are formed on the semiconductor layer 116b. A portion of the semiconductor layer 116b located between the source 116c and a drain 116d is a channel with a width “W” and a length “L”. The operating rate of the TFT 116 is faster while the channel has a wider width W and a shorter length L. However, the semiconductor layer 116b formed on the scan line 112 has definite area, so that the width W of the channel is difficult to increase.

Further, the TFT 116 should be turned on for controlling the voltage applied on the pixel electrode 118 while display device displays predefine images. Then, the liquid crystal molecules (not shown) between the pixel electrode 118 and a common electrode (not shown) disposed on the color filter substrate (not shown) is deflected. The polarizing direction of the light piercing the liquid crystal molecules is transferred by the deflection angles of the liquid crystal molecules. Thus, partial polarized light can pass through the polarizer disposed on the color filter substrate to display an image. It should be noted that the liquid crystal molecules have a liquid crystal capacitance C_{LC} coupled by the pixel electrode 118 and the common electrode disposed on the color filter substrate during applying voltage to the pixel electrode 118.

When TFT 116 is turned off, the voltage applied on the liquid crystal capacitance C_{LC} is still maintained to be a constant, but due to an overlap area of the gate 116a and the drain 116d is formed between them, a gate-drain parasitic capacitance C_{gd} exists between the gate 116a and the drain 116d. Thus, the maintained voltage applied on the liquid crystal capacitance C_{LC} may be varied with the signals on the data line 114, so that the voltage maintained on the liquid crystal capacitance C_{LC} is diverged from the preset value. The voltage variation is so-called feed-through voltage ΔVp, and it can be expressed to be the following formula:
ΔVp=(C_{gd}/(C_{gd}+Cₛₜ+C_{lc}))·ΔV_{g} (1)

In the formula (1), ΔVg is the amplitude of a pulse voltage applied on the scan line 112, and Cₛₜ is a storage capacitance.

Therefore, the ΔVp is reduced with the gate-drain parasitic capacitance C_{gd}. In other words, the variation of the feed-through voltage can be reduced to prevent the displayed images from resulting mura or flicker.

### SUMMARY OF THIS INVENTION

Accordingly, the purpose of this invention is to provide a thin film transistor for increasing the ratio of the W/L of channel and reducing the gate-drain parasitic capacitance C_{gd}.

The another purpose of this invention is to provide a thin film transistors array substrate, wherein the TFTs may increase the ratio of the W/L of channel and reduce the gate-drain parasitic capacitance C_{gd}.

This invention provides a thin film transistor comprising a gate, a gate insulating layer, a channel layer, a spiral source and a spiral drain. The gate is covered by the gate insulating layer. The channel layer is formed on the gate insulating layer above the gate. The spiral source and the spiral drain are formed on the channel layer above the gate. Wherein, the spiral source and the spiral drain are curled with each other.

In this invention, a TFTs array substrate comprising a substrate, scan lines, data lines, TFTs and pixel electrodes is provided. The scan lines and the data lines are disposed on the substrate to define a plurality of pixel regions. Each of the TFTs is disposed in one of the pixel regions on the substrate and driven by the scan line and the data line. Each of the TFTs comprises a gate, a gate insulating layer, a channel layer, a spiral source and a spiral drain. The gate is covered by the gate insulating layer. The channel layer is formed on the gate insulating layer above the gate. The spiral source and the spiral drain are formed on the channel layer above the gate. Wherein, the spiral source and the spiral drain are curled with each other. Each of the pixel electrodes is disposed in one of the pixel regions on the substrate and electrically connected to the corresponding TFT.

In some embodiments of this invention, the spiral source and the spiral drain are counter clockwise.

In some embodiments of this invention, the spiral source and the spiral drain are clockwise.

In some embodiments of this invention, the gates and the scan lines are formed by using the same metal layer.

In some embodiments of this invention, the spiral source is electrically connected with one of the data lines.

In some embodiments of this invention, the spiral drain is electrically connected with one of the pixel electrodes.

Due to this invention use the spiral source and the spiral drain, the width (W) of the channel with limited area may be widened without varying the length (L), so that the ratio of the width to the length can be increased. Furthermore, this design in the TFT can reduce the gate-drain parasitic capacitance C_{gd} and the feed-through voltage ΔVp. Therefore, a display panel including the TFT can prevent from resulting the mura or flicker.

### BRIEF DESCRIPTION OF THE DRAWINGS

FIG. 1 is a schematic top view of a conventional TFTs array substrate.

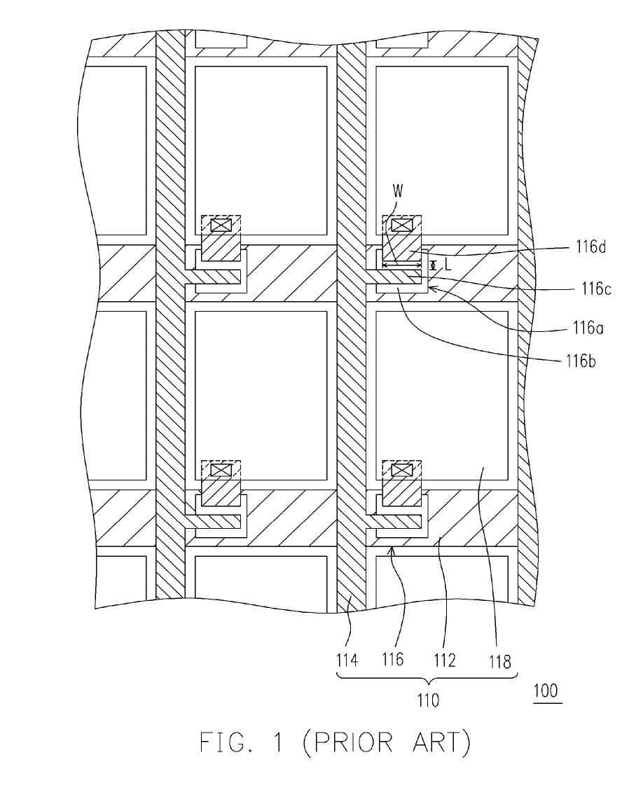

FIG. 2 is a schematic top view of a TFT according to one embodiment of this invention.

FIG. 2A is a schematic cross-section view along the A-A′ in FIG. 2.

FIG. 3 is a schematic top view of another TFT according to another embodiment of this invention

FIG. 4 is a schematic top view of a TFTs array substrate according to an embodiment of this invention.

### DETAILED DESCRIPTION OF THE EMBODIMENTS

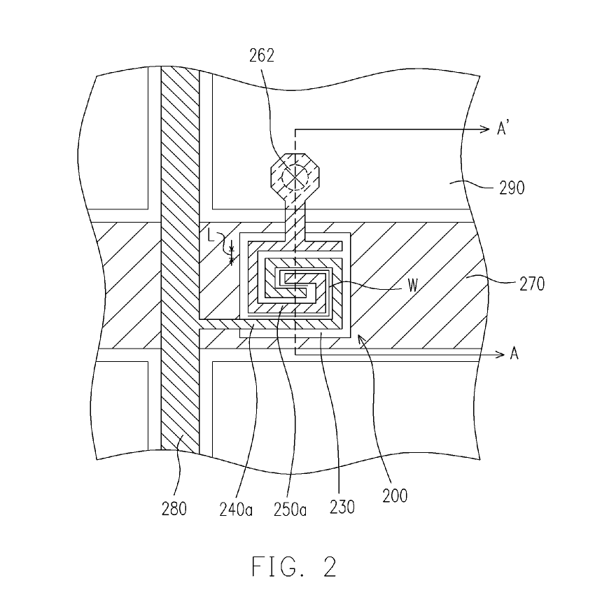

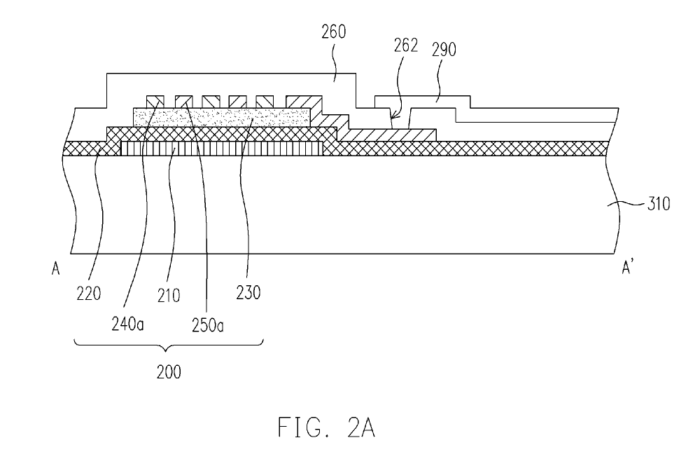

FIG. 2 is a schematic top view of a TFT according to one embodiment of this invention. FIG. 2A is a schematic cross-section view along the A-A′ in FIG. 2.

Referring to FIG. 2 and FIG. 2A, a TFT 200 comprises a gate 210, a gate insulating layer 220, a channel layer 230 , a spiral source 240a and a spiral drain 250a. The gate 210 is covered by the gate insulating layer 220. The channel layer 230 is formed on the gate insulating layer 220 above the gate 210. The spiral source 240a and the spiral drain 250a are formed on the channel layer 230 above the gate 210. Wherein, the spiral source 240a and the spiral drain 250a are curled with each other.

A pixel structure comprises the TFT 200, a scan line 270, a data line 280, and a pixel electrode 290. In general, the TFT 200 is covered by a passivation layer 260 with an opening 262, and the pixel electrode 290 is electrically connected with the TFT 200 via the opening 262.

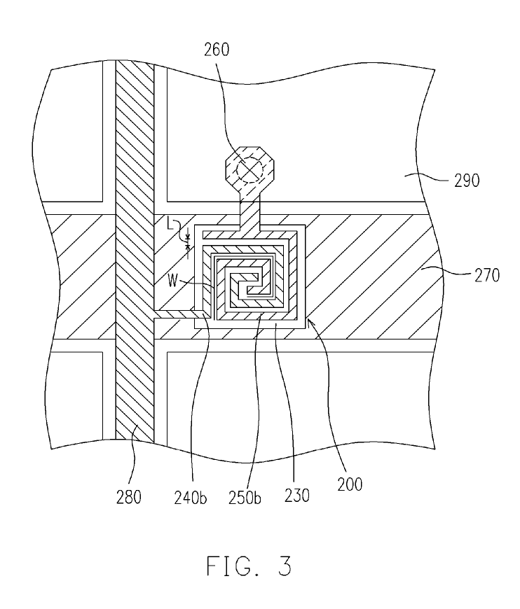

It should be noted that in one embodiment of this invention, the spiral source 240a and the spiral drain 250a are counter clockwise as shown in FIG. 2. However, the spiral source 240b and the spiral drain 250b is clockwise as shown in FIG. 3 in another embodiment of this invention. According to FIG. 2 and FIG. 3, due to the spiral source 240a and the spiral drain 250a are curled with each other, and the spiral source 240b and the spiral drain 250b are also curled with each other, this invention may increase the channel width W efficiently and maintain the channel length L almost to be a constant even if the area of the channel layer 230 is limited. Thus, the ratio of the W/L of the channel can be increased. Furthermore, this invention may further adjust the ratio of the W/L ratio of the channel appropriately by changing the curling circle numbers of the spiral source 240a, 240 b and the spiral source 250 a, 250 b.

In more detail, due to the channel can be formed beside the spiral source 240 a, the operating rate of the TFT 200 can be raised. Moreover, the shapes of the spiral source 240a, 240band the spiral drain 250a, 250b are not limited to the squares shown in FIG. 2 and FIG. 3, but also can be circles, ellipses or polygons etc.

In addition, the parasitic capacitance, which is called “C_{gd}” in following description, between the gate and the drain of the TFT 200 may be reduced. According to the formula of feed-through voltage (which is called “ΔVp” in following description)
ΔVₚ=(C_{gd}/(C_{gd}+Cₛₜ+C_{lc}))·ΔV_{g} (1),

the ΔVp is reduced as well as the C_{gd}.

The ratio of the W/L of the TFT 200 of this invention is adjusted to close the ratio of the W/L of the conventional TFT 110 for further proving the TFT 200 of this invention has the lower C_{gd} and ΔVp. Table 1 is the result of comparing the C_{gd} and ΔVp of the conventional TFT 110 and the TFT 200 of this invention.

TABLE 1

| | Conventional TFT | TFT of this invention |
|---|---|---|
| W/L | 35/3 | 36/3 |
| C_{gd} (F) | 2.04E−14 | 1.7E−14 |
| Vp (V) | 0.486 | 0.406 |

According to Table 1, the C_{gd} of the TFT 200 of this invention is reduced about 16.65%, and ΔVp is reduced about 16.48%. Thus, the spiral source 240a , 240b and the spiral drain 250a, 250b of this invention truly can efficiently reduce the C_{gd} and ΔVp. The following description will describe an embodiment in that the TFT 200 of this invention is applied in a TFTs array substrate.

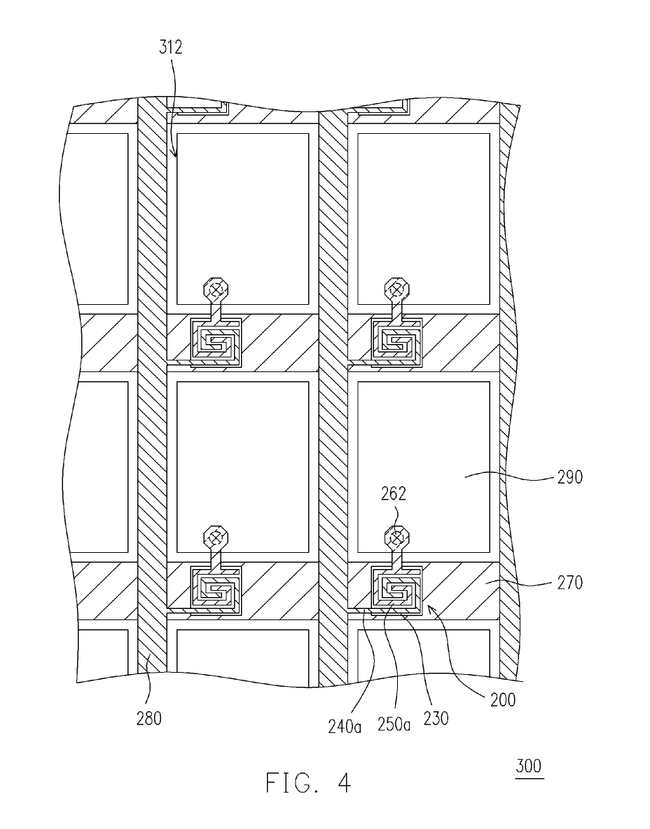

FIG. 4 is a schematic top view of a TFTs array substrate according to an embodiment of this invention. Refereeing to FIG. 2A and FIG. 4, the TFTs array substrate 300 comprises substrate 310, a plurality of scan lines 270, a plurality of data lines 280, a plurality of TFTs 200 and a plurality of pixel electrodes 290. The plurality of scan lines 270 and the plurality of data lines 280 are disposed on the substrate 310 to define a plurality of pixel regions 312. Each of the TFTs 200 is disposed in one of the pixel regions 312 on the substrate 310 and driven by the scan line 270 and the data line 280. The TFT 200 is described in FIG. 2, FIG. 2A or FIG. 3. Each of the pixel electrodes 290 is disposed in one of the pixel regions 312 on the substrate 310 and electrically connected to the corresponding TFT 200.

In one embodiment of this invention, the gate 210 and the scan line 270 are formed by using the same metal layer, that is, a portion of the scan line 270 is used as the gate 210 of the TFT 200. In addition, the spiral source 240a is electrically connected to one of the data lines 280, and the spiral drain 250a is electrically connected to one of the pixel electrodes 290.

Because the particular design of the TFT 200 can efficiently reduce the ΔVp as well as C_{gd} in the TFTs array substrate 300, the TFTs array substrate 300 has good operating characteristic. Therefore, the mura or flicker problem resulted from the larger feed-through voltage ΔVp in a display panel with the TFTs array substrate 300 may be solved.

In summary, the TFT and the TFTs array substrate have the following advantages:

(1) Due to the spiral source and the spiral drain of this invention, the ratio of the W/L of the channel with limited area may be increased.

(2) Because the channel is formed beside the spiral source, the operating rate of the TFT can be raised.

(3) In the TFT of the invention, the feed-through voltage ΔVp can be reduced as the parasitic capacitance C_{gd} resulted between the gate and the drain Therefore, the mura or flicker problem resulted from the larger feed-through voltage ΔVp in the display panel using the TFTs array substrate comprising the TFT of this invention may be solved.

While this invention has been described with embodiments, this description is not intended to limit our invention. Various modifications of the embodiment will be apparent to those skilled in the art. It is therefore contemplated that the appended claims will cover any such modifications or embodiments as fall within the true scope of this invention.

What is claimed is:

1. A thin film transistor, comprising:
a gate;
a gate insulating layer covering the gate;
a channel layer formed on the gate insulating layer above the gate;
a spiral source formed on the channel layer above the gate; and
a spiral drain formed on the channel layer above the gate, wherein the spiral source and the spiral drain are curled with each other.

2. The thin film transistor of claim 1, wherein the spiral source and the spiral drain are counter clockwise.

3. The thin film transistor of claim 1, wherein the spiral source and the spiral drain are clockwise.

4. A thin film transistors array substrate, comprising:
a substrate;
a plurality of scan lines disposed on the substrate;
a plurality of data lines disposed on the substrate, wherein a plurality of pixel regions is defined on the substrate by the plurality of scan lines and the plurality of data lines;
a plurality of thin film transistors disposed on the substrate and driven by the plurality of scan lines and the plurality of data lines, each of the thin film transistors located in one of the pixel regions comprises:
a gate;
a gate insulating layer covering the gate;
a channel layer formed on the gate insulating layer above the gate;
a spiral source formed on the channel layer above the gate;
a spiral drain formed on the channel layer above the gate, wherein the spiral source and the spiral drain are curled with each other; and
a plurality of pixel electrodes disposed on the substrate, each of the pixel electrodes located in one of the pixel regions is electrically connected to the corresponding thin film transistor.

5. The thin film transistors array substrate of claim 4, wherein the spiral sources and the spiral drains are counter clockwise.

6. The thin film transistors array substrate of claim 4, wherein the spiral sources and the spiral drains are clockwise.

7. The thin film transistors array substrate of claim 4, wherein the gates and the scan lines are formed by using the same metal layer.

8. The thin film transistors array substrate of claim 4, wherein one of the spiral sources is electrically connected to one of the data lines.

9. The thin film transistors array substrate of claim 4, wherein one of the spiral drains is electrically connected to one of the pixel electrodes.
